(19) United States
(12) Patent Application Publication
(10) Pub. No.: US 2009/0206846 A1
(43) Pub. Date: Aug. 20, 2009

(54) Capacitor-based position sensor for vehicle

(76) Inventors: Francisco J. Sanchez, El Paso, TX (US); Carlos A. Urquidi, CD. Juarez (MX)

Correspondence Address: DELPHI TECHNOLOGIES, INC., M/C 480-410-202, PO BOX 5052, TROY, MI, 48007, US

(21) Appl. No.: 12/069,963

(22) Filed: Feb. 14, 2008

(51) Int. Cl. G01R 27/26

(52) U.S. Cl. 324/662

(57) ABSTRACT

A position sensor has an external moving element couplable to a moving part whose angular or linear position is sought to be sensed. A sealed enclosure is engaged with the moving element such that the moving element moves relative to the enclosure, and capacitive elements are in the enclosure. An internal moving element inside the enclosure is magnetically coupled to the external moving element for movement with the external element, with the internal moving element moving between the capacitive elements thereby change the capacitance between the capacitive elements as the external moving element moves.

### FIELD OF THE INVENTION

The present invention relates generally to capacitor-based vehicle position sensors.

### BACKGROUND OF THE INVENTION

A variety of vehicle systems require knowing the angular or linear position (and/or their derivatives of angular or linear velocity) of various components. For example, in drive-by-wire systems the position of an accelerator pedal must be known to know how much fuel to inject into the engine, since mechanical linkages between the throttle and pedal may not exist. As another example, the angular position of a crankshaft, if known, can be used in distributorless ignition systems that have selectively energized ignition coils that fire the spark plugs as appropriate for the angular position of the crankshaft. Moreover, the crankshaft angular position signals can be used for combustion control and diagnostic functions.

While contact position sensors have been used, for a number of reasons contactless position sensors are preferred. Magnetic-based contactless sensors that use, e.g., Hall sensors have been introduced and while effective, tend to require a plethora of parts such as flux concentrators that increase the complexity and expense of the sensor.

As understood herein, capacitor-based contactless sensors can be used to sense position, but suffer from the drawback of contaminant build-up between the plates (typically, one plate on the moving part and one on the non-moving part) that establish the capacitor. This eventually ruins the ability of the sensor to function. With this critical recognition in mind, the invention herein is provided.

### SUMMARY OF THE INVENTION

A position sensor includes an external moving element couplable to a moving part whose position is sought to be sensed. A sealed enclosure is engaged with the moving element such that the moving element moves relative to the enclosure, and first and second capacitive elements are in the enclosure and define a plane between them. An internal moving element is inside the enclosure and is magnetically coupled to the external moving element for movement therewith. The internal moving element moves in the plane to thereby change the capacitance between the capacitive elements as the external moving element moves.

The plane can be a vertical plane midway between the capacitive elements, and furthermore can be orthogonal to a horizontal plane in which both capacitive elements lie, with the internal moving element moving along the intersection of the planes.

In some embodiments the moving parts move linearly with respect to the capacitor electrodes. In other embodiments the internal element revolves with respect to the capacitor electrodes as the external element rotates. The internal moving part can be metal or it can be plastic overmolded onto an internal magnet.

In another aspect, a sensor includes a capacitor and a first moving element disposed for movement relative to the capacitor to change a capacitance thereof in response to linear motion of a second moving element that is wirelessly coupled to the first moving element. The capacitor is not exposed to contaminants in the environment of the second moving element.

In still another aspect, a sensor includes a capacitor and a first moving element disposed for movement relative to the capacitor to change a capacitance thereof in response to rotational motion of a second moving element that is wirelessly coupled to the first moving element. The capacitor is not exposed to contaminants in the environment of the second moving element.

The details of the present invention, both as to its structure and operation, can best be understood in reference to the accompanying drawings, in which like reference numerals refer to like parts, and in which:

### BRIEF DESCRIPTION OF THE DRAWINGS

FIG. 1 is a perspective view of a first embodiment of a linear position sensor in accordance with present principles, with portions of the housing cut away for clarity;

FIG. 2 is a perspective view of a second embodiment of a linear position sensor in accordance with present principles, with portions of the housing cut away for clarity;

FIG. 3 is a perspective view of a first embodiment of an angular position sensor in accordance with present principles, with portions of the housing cut away for clarity; and

FIG. 4 is an exploded perspective view of a second embodiment of an angular position sensor in accordance with present principles.

### DETAILED DESCRIPTION OF THE PREFERRED EMBODIMENT

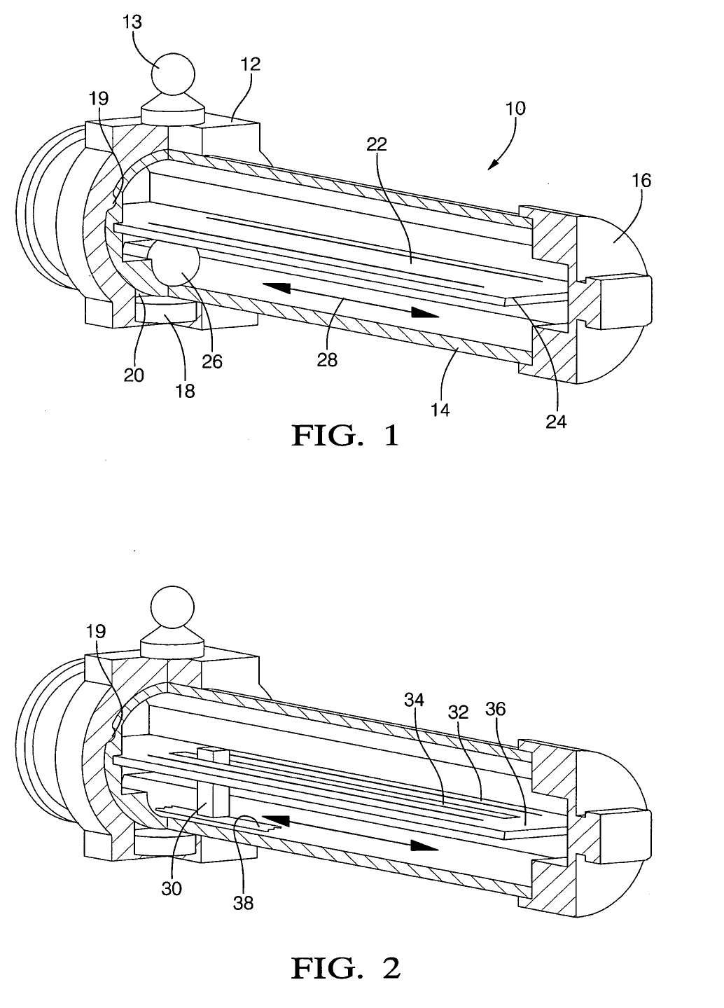

Referring initially to FIG. 1, a linear position sensor is shown, generally designated 10, that includes a sliding element 12 which is external to and which moves linearly relative to a sealed housing 14. The sliding element 12 can be coupled via a coupling post 13 to a vehicle component that moves linearly so that as the component moves, the sliding element 12 moves relative to the housing 14. In the particular embodiment shown, the housing 14 is a hollow, generally cylindrical structure the ends of which can be covered by base covers 16, while the sliding element 12 establishes a movable collar around the housing 14. One or more magnets 18 are coupled to the sliding element 12 by, e.g., press-fitting the magnet 18 into a magnet receptacle 20 of the sliding element 12. The sliding element 12 can be formed with anti-rotating structure such as but not limited to a guide protrusion 19 that moves in a groove or slot formed in the housing 14 to prevent rotational motion of the sliding element 12 on the housing 14.

As shown in FIG. 1, the housing 14 defines an enclosure that is sealed from the sliding element 12 and, hence, that is not exposed to contaminants in the environment of the sliding element 12. A capacitor is in the enclosure, and in the embodiment shown the capacitor may be established by two parallel electrodes 22 on a circuit board 24, it being understood that the electrodes can be oriented obliquely to each other or shaped with non-parallel edges or configurations such that the distance between them varies along their lengths. The circuit board 24 can include circuitry for outputting a signal representative of the capacitance of the capacitor, i.e., representative of the capacity of the capacitor to store electrical charge between the electrodes. In turn, the circuit board 24 may be connected (via, e.g., a sealed wire passageway) to a control system that may include, e.g., a vehicle engine control module.

FIG. 1 shows that an internal moving element 26 such as a metal ball is movably disposed in the enclosure for linear movement as indicated by the arrow 28 relative to the capacitor. It will be appreciated in reference to FIG. 1 that the electrodes 22 define a vertical plane between them, for instance, midway between them, and the moving element 26 moves in this plane, albeit in the embodiment shown not in the horizontal plane in which both electrodes 22 lie. However, referring briefly to FIG. 2, a moving element 30 may be provided which moves in both the vertical plane defined between capacitor electrodes 32 as well as in the horizontal plane in which both electrodes 32 lie, in which case an elongated slot 34 may be formed in a circuit board 36 bearing the electrodes 32 to accommodate the moving element 30, which may be configured as an upright metal post or bar as shown. A channel 38 may be formed in the housing to guide the opposite end of the moving element 32 as it moves. The embodiment of FIG. 2 typically yields a larger signal than that of FIG. 1. The devices of FIGS. 1 and 2 are in all other essential respects identical to each other.

In any case and referring back to FIG. 2 for ease of description, the internal moving element 26 is wirelessly coupled (and in the embodiment shown is magnetically coupled by means of the magnet 18) to the external sliding element 12. It is to be further appreciated that as the moving element 26 moves, it changes the capacitance of the capacitor established by the electrodes 22 and thus the signal that is output by the circuit board 24. Accordingly, as the component whose position is sought to be sensed moves, the sliding element 12 with magnet 18 moves with it, which through magnetic coupling in turn causes the internal moving element 26 to move and change the capacitance of the capacitor. Hence, capacitance is proportional to the linear position of the sliding element 12.

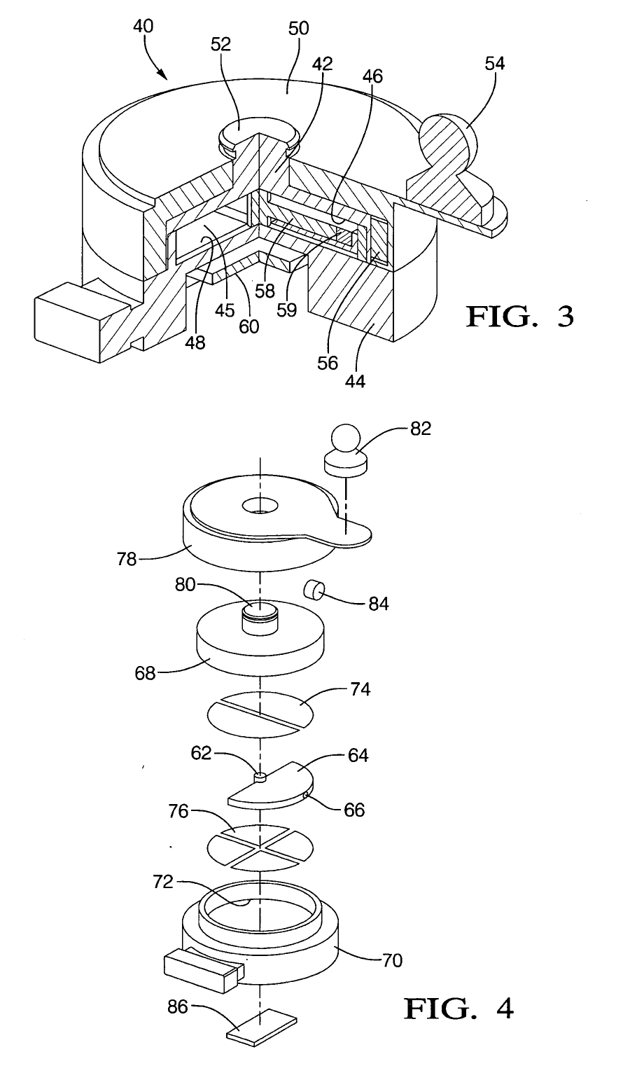

Present principles may be adapted to provide an angular position sensor 40 as shown in FIG. 3. Upper and lower generally disk-shaped fixed plastic electrode holders 42, 44 can define a sealed enclosure 45 between them, and each can bear, on its inner base, a respective arcuate electrode 46, 48. An external generally disk-shaped moving element 50 can be rotatably engaged with the upper and lower plastic electrode holders 42, 44 about an axle 52. The external moving element 50 may be coupled via a coupling post 54 to a part such as a steering wheel column or other rotating component of a vehicle whose angular position is sought to be measured. A magnet 56 is affixed to the external moving element 50 outside the enclosure 45.

In accordance with present principles, an internal moving element 58 such as a piece of metal or a piece of plastic overmolded onto a magnet revolves in the enclosure 45 between the electrodes 46, 48. A magnet or piece of metal 59 is engaged with the moving element 58. The internal moving element 58 is magnetically coupled through the magnet 56 to the external moving element 50, such that as the external moving element 50 rotates, the internal moving element 58 revolves in the enclosure 45 between the electrodes 46, 48 to change the capacitance of the capacitor established by the electrodes. Electrical circuitry on a circuit board 60 is connected to the electrodes and to an external controller to provide a signal representative of the capacitance of the electrodes and, hence, of the angular position of the external moving element 50.

FIG. 4 shows further details of the angular position sensor except that instead of a completely metal internal moving element, a moving element 62 is provided that has a semi-disk shaped plastic part 64 that is overmolded onto an internal magnet 66 or internal piece of metal. In all other essential respects the sensor in FIG. 4 can be substantially identical to that in FIG. 3, including upper and lower generally disk-shaped fixed plastic electrode holders 68, 70 that define a sealed enclosure 72 between them, with each bearing, on its inner base, a respective arcuate electrode 74, 76. In the embodiment shown in FIG. 4, the upper electrode 74 has two co-planar semi-disk portions with their straight edges facing each other as shown, while the lower electrode 76 has four co-planar quarter-disk portions with their straight edges facing each other.

An external generally disk-shaped moving element 78 can be rotatably engaged with an axle 80 formed by the upper plastic electrode holder 68. The external moving element 78 may be coupled via a coupling post 82 to a part such as a steering wheel column or other rotating component of a vehicle whose angular position is sought to be measured. A disk-shaped magnet 84 is affixed to the external moving element 78 outside the enclosure 72.

In accordance with present principles, the internal moving element 62 disposed in the enclosure 72 between the electrodes 74, 76. The internal moving element 62 is magnetically coupled through the magnet 84 to the external moving element 78, such that as the external moving element 78 rotates, the internal moving element 62 revolves in the enclosure 72 between the electrodes 74, 76 to change the capacitance of the capacitor established by the electrodes. Electrical circuitry on a circuit board 86 is connected to the electrodes and to an external controller to provide a signal representative of the capacitance of the electrodes and, hence, of the angular position of the external moving element 78.

Alternatively, the sensor can measure angular position with respect to ground if it is mounted vertically, in which case the moving element changes it position with respect to ground under the influence of gravity, obviating the need for an external magnet in the external moving element.

The sealed enclosures described herein may be filled with air or a fluid with a known dielectric constant. The plastic parts preferably are selected to incorporate plastic of low permeability to avoid liquid intrusion.

While the particular CAPACITOR-BASED POSITION SENSOR FOR VEHICLE is herein shown and described in detail, it is to be understood that the subject matter which is encompassed by the present invention is limited only by the claims.

What is claimed is:

1. A position sensor, comprising:
an external moving element couplable to a moving part whose position is sought to be sensed;
a sealed enclosure juxtaposed with the moving element such that the moving element moves relative to the enclosure;
at least first and second capacitive elements in the enclosure and defining a plane therebetween; and
an internal moving element inside the enclosure and magnetically coupled to the external moving element for movement therewith, the internal moving element moving in the plane to thereby change the capacitance between the capacitive elements as the external moving element moves.

2. The sensor of claim 1, wherein the plane is midway between the capacitive elements.

3. The sensor of claim 1, wherein the plane is a first plane and is orthogonal to a second plane, both capacitive elements lying in the second plane, the internal moving element moving in both the first and second planes.

4. The sensor of claim 1, wherein the moving parts move linearly.

5. The sensor of claim 1, wherein at least the internal moving part revolves.

6. The sensor of claim 1, wherein the internal moving part is metal.

7. The sensor of claim 1, wherein the internal moving part is plastic overmolded onto an internal magnet.

8. A sensor comprising:
a capacitor; and
a first moving element disposed for movement relative to the capacitor to change a capacitance thereof in response to linear motion of a second moving element wirelessly coupled to the first moving element, the capacitor not being exposed to contaminants in the environment of the second moving element.

9. The sensor of claim 8, wherein the first moving element is sealed in a housing with the capacitor.

10. The sensor of claim 8, wherein the moving elements are magnetically coupled with each other.

11. The sensor of claim 8, wherein the capacitor includes at least first and second capacitive elements defining a plane therebetween, the first moving element moving in the plane to thereby change the capacitance between the capacitive elements as the second moving element moves.

12. The sensor of claim 11, wherein the plane is midway between the capacitive elements.

13. The sensor of claim 11, wherein the plane is a first plane and is orthogonal to a second plane, both capacitive elements lying in the second plane, the internal moving element moving in both the first and second planes.

14. The sensor of claim 8, wherein the first moving part is metal.

15. The sensor of claim 8, wherein the first moving part is plastic overmolded onto an internal magnet.

16. A sensor comprising:
a capacitor; and
a first moving element disposed for movement relative to the capacitor to change a capacitance thereof in response to rotational motion of a second moving element wirelessly coupled to the first moving element, the capacitor not being exposed to contaminants in the environment of the second moving element.

17. The sensor of claim 16, wherein the first moving element is sealed in a housing with the capacitor.

18. The sensor of claim 16, wherein the moving elements are magnetically coupled with each other.
